(19) United States
(12) Patent Application Publication
(10) Pub. No.: US 2023/0266076 A1
(43) Pub. Date: Aug. 24, 2023

(54) TWO-PHASE IMMERSION-TYPE HEAT DISSIPATION STRUCTURE

(71) Applicant: AMULAIRE THERMAL TECHNOLOGY, INC., New Taipei City (TW)

(72) Inventors: CHENG-SHU PENG, New Taipei City (TW); CHUN-LI HSIUNG, New Taipei City (TW)

(21) Appl. No.: 17/676,208

(22) Filed: Feb. 20, 2022

(51) Int. Cl. F28F 3/04

(52) U.S. Cl. CPC F28F 3/04

(57) ABSTRACT

A two-phase immersion heat dissipation structure is provided. The two-phase immersion heat dissipation structure includes an immersion-type heat dissipation substrate, a fin assembly, and a metal reinforcement frame. The immersion-type heat dissipation substrate has an upper surface having the fin assembly arranged vertically thereon and a lower surface used for contacting a heat generating element. The metal reinforcement frame is surroundingly in contact with a peripheral wall of the immersion-type heat dissipation substrate, and the metal reinforcement frame has two reinforcement side walls correspondingly protruding from a surface thereof. The two reinforcement side walls are arranged opposite to each other, and a height of the reinforcement side wall is between 5 mm and 15 mm. Each of the two reinforcement side walls has a plurality of through holes that horizontally pass through the reinforcement side wall and that are used for a replenishment of a two-phase coolant.

### FIELD OF THE DISCLOSURE

The present disclosure relates to a heat dissipation structure, and more particularly to a two-phase immersion type heat dissipation structure.

### BACKGROUND OF THE DISCLOSURE

An immersion cooling technology is to directly immerse heat generating elements (such as servers and disk arrays) into a coolant that is non-conductive, and heat generated from operation of the heat generating elements is removed through an endothermic gasification process of the coolant. Therefore, how to dissipate heat more effectively through the immersion cooling technology has long been an issue to be addressed in the industry.

### SUMMARY OF THE DISCLOSURE

In response to the above-referenced technical inadequacy, the present disclosure provides a two-phase immersion-type heat dissipation structure.

In one aspect, the present disclosure provides a two-phase immersion-type heat dissipation structure, which includes an immersion-type heat dissipation substrate, a fin assembly, and a metal reinforcement frame. The immersion-type heat dissipation substrate has an upper surface and a lower surface that are opposite to each other, the lower surface is used for contacting a heat generating element, and the upper surface has the fin assembly arranged vertically thereon. The metal reinforcement frame is surroundingly in contact with a peripheral wall of the immersion-type heat dissipation substrate, and the metal reinforcement frame has two reinforcement side walls that correspondingly protrude from a surface of the metal reinforcement frame. The two reinforcement side walls are arranged opposite to each other, and a height of each of the two reinforcement side walls is between 5 mm and 15 mm. Each of the two reinforcement side walls has a plurality of through holes that horizontally pass through the reinforcement side wall and that are used for a replenishment of a two-phase coolant.

In certain embodiments, the immersion-type heat dissipation substrate is made of aluminum, copper, or alloys thereof, and the metal reinforcement frame is made of copper, aluminum, titanium, iron, or alloys thereof.

In certain embodiments, the immersion-type heat dissipation substrate is a porous metal heat dissipation substrate that has a porosity greater than 5% and that is immersed in the two-phase coolant.

In certain embodiments, the fin assembly includes a plurality of porous fins, and a porosity of the fin assembly is greater than the porosity of the immersion-type heat dissipation substrate.

In certain embodiments, the upper surface of the immersion-type heat dissipation substrate has at least one reinforcement structure formed thereon, the fin assembly includes a plurality of porous fins, and a projection area of the at least one reinforcement structure on the upper surface of the immersion-type heat dissipation substrate is two times or more larger than a projection area of any one of the plurality of porous fins on the upper surface of the immersion-type heat dissipation substrate.

In another aspect, the present disclosure provides a two-phase immersion-type heat dissipation structure, which includes an immersion-type heat dissipation substrate, a fin assembly, a metal reinforcement frame, and a structural reinforcement member. The immersion-type heat dissipation substrate has an upper surface and a lower surface that are opposite to each other, the lower surface is used for contacting a heat generating element, and the upper surface has the fin assembly arranged vertically thereon. The metal reinforcement frame is surroundingly in contact with a peripheral wall of the immersion-type heat dissipation substrate, the structural reinforcement member that has a frame shape is disposed on the metal reinforcement frame, and the structural reinforcement member has two reinforcement side walls that correspondingly protrude from a surface of the structural reinforcement member. The two reinforcement side walls are arranged opposite to each other and respectively abut a right side and a left side of the upper surface of the immersion-type heat dissipation substrate, and a height of each of the two reinforcement side walls is between 5 mm and 15 mm. Each of the two reinforcement side walls has a plurality of through holes that horizontally pass through the reinforcement side wall and that are used for a replenishment of a two-phase coolant.

In certain embodiments, the immersion-type heat dissipation substrate is made of aluminum, copper, or alloys thereof, the metal reinforcement frame is made of copper, aluminum, titanium, iron, or alloys thereof, and the structural reinforcement member is made of copper, aluminum, titanium, iron, or alloys thereof.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic top view of a two-phase immersion-type heat dissipation structure according to a first embodiment of the present disclosure;

FIG. 2 is a cross-sectional view taken along line II-II of FIG. 1;

FIG. 3 is a schematic top view of a two-phase immersion-type heat dissipation structure according to a second embodiment of the present disclosure;

FIG. 4 is a schematic top view of a two-phase immersion-type heat dissipation structure according to a third embodiment of the present disclosure; and

FIG. 5 is a cross-sectional view taken along line V-V of FIG. 4.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

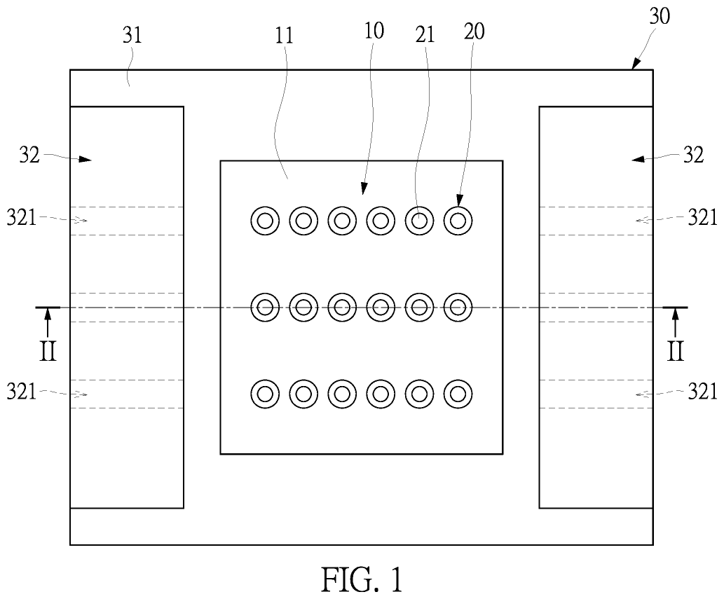

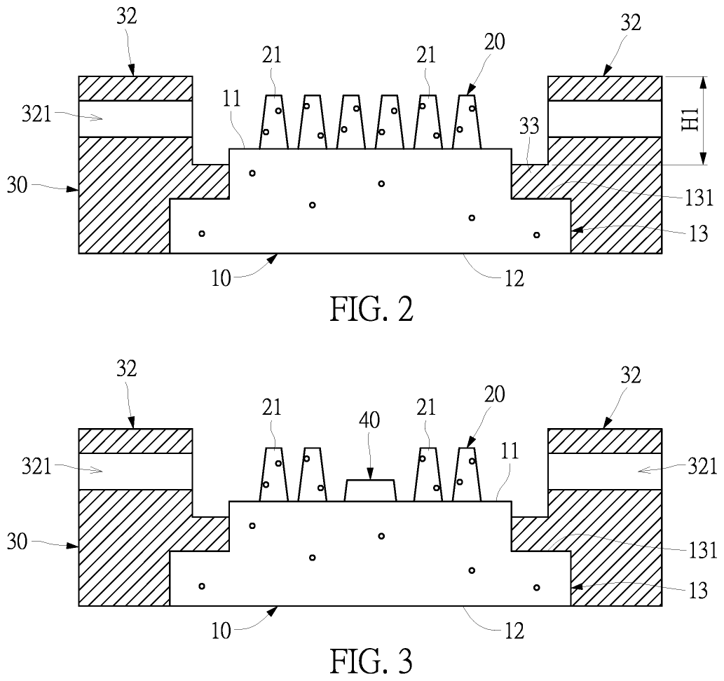

Reference is made to FIG. 1 and FIG. 2, in which one embodiment of the present disclosure is shown. Embodiments of the present disclosure provide a two-phase immersion-type heat dissipation structure that can be used for contacting a heat generating element. As shown in FIG. 1 and FIG. 2, the two-phase immersion-type heat dissipation structure provided by the embodiments of the present disclosure essentially includes an immersion-type heat dissipation substrate 10, a fin assembly 20, and a metal reinforcement frame 30.

In the present embodiment, the immersion-type heat dissipation substrate 10 can be made of a high thermally conductive material, such as aluminum, copper, and alloys thereof. Further, the immersion-type substrate 10 of the present embodiment can be a porous metal heat sink that can be immersed in a two-phase coolant (such as electronic fluorinated liquid) and that has a porosity greater than 5%. Accordingly, generation of vapor bubbles can be increased and an immersion-type heat dissipation effect can be enhanced. In addition, the porosity of the immersion-type heat dissipation substrate 10 of the present embodiment is configured to be between 5% and 50%.

In the present embodiment, the immersion-type heat dissipation substrate 10 has an upper surface 11 and a lower surface 12 that are opposite to each other. The lower surface 12 of the immersion-type heat dissipation substrate 12 is used for contacting the heat generating element. In addition, the upper surface 11 of the immersion-type heat dissipation substrate 10 has the fin assembly 20 arranged thereon vertically, that is, the fin assembly 20 is perpendicular to the upper surface 11 of the immersion-type heat dissipation substrate 11.

In the present embodiment, the fin assembly 20 includes a plurality of porous fins 21, and each of the plurality of porous fins 21 can be a pin fin, a plate fin, or a composite fin. Moreover, a porosity of the fin assembly 20 is greater than the porosity of the immersion-type heat dissipation substrate 10, so that generation of vapor bubbles is increased by the fin assembly 20, thereby increasing the immersion-type heat dissipation effect.

Furthermore, since the immersion-type heat dissipation substrate 10 of the type-phase immersion-type heat dissipation structure of the present embodiment is a porous metal heat dissipation substrate with a weaker structural strength, a demand for higher structural strength cannot be met. Therefore, the metal reinforcement frame 30 of the present embodiment is surroundingly in contact with a peripheral wall 13 of the immersion-type heat dissipation substrate 10, so as to strengthen an overall structure of the two-phase immersion-type heat dissipation structure. The metal reinforcement frame can be made of copper, aluminum, titanium, iron, or alloys thereof. In addition, the metal reinforcement frame 30 has two reinforcement side walls 32 that correspondingly protrude from a surface 21 of the metal reinforcement frame 30. Each of the two reinforcement side walls 32 can be elongated, and the two reinforcement side walls 32 are arranged opposite to each other. Moreover, a height H1 of each of the two reinforcement side walls 32 is configured to be between 5 mm and 15 mm, so as to strengthen two sides of the overall structure of the two-phase immersion-type heat dissipation structure. Furthermore, each of the two reinforcement side walls 32 has a plurality of through holes 321 that horizontally pass through the reinforcement side wall 32, so that the two-phase coolant can be laterally replenished into a region where the vapor bubbles are generated, so as to further increase the immersion-type heat dissipation effect.

In addition, a part of the peripheral wall 13 of the immersion-type heat dissipation substrate 10 of the present embodiment can also be recessed inward to form a step surface 131, so that the immersion-type heat dissipation substrate of the present embodiment can be a porous metal heat dissipation substrate having a step structure. Moreover, an inner peripheral edge of the metal reinforcement frame 30 protrudes outward to form a protrusion 33, and the protrusion 33 abuts against the step surface 131, so that the metal reinforcement frame 30 is more firmly in contact with the immersion-type heat dissipation substrate 10.

### Second Embodiment

Reference is made to FIG. 3, in which a second embodiment of the present disclosure is shown. The second embodiment is substantially the same as the first embodiment, and differences therebetween are described as follows.

In the present embodiment, the upper surface 11 of the immersion-type heat dissipation substrate 10 further has a reinforcement structure 40 formed thereon, and the reinforcement structure 40 is used for reinforcing a structural strength of the immersion-type heat dissipation substrate 10. The reinforcement structure 40 of the present embodiment can be an integral reinforcement structure protruding from a center of the upper surface 11 of the immersion-type heat dissipation substrate 10, that is, the reinforcement structure 40 can be connected to the upper surface 11 of the immersion-type heat dissipation substrate 10 by metal injection molding. The reinforcement structure 40 of the present embodiment can also be connected to the upper surface 11 of the immersion-type heat dissipation substrate 10 in a non-integral manner, that is, the reinforcement structure 40 can be a sintered structure formed on the upper surface 11 of the immersion-type heat dissipation structure 10 by sintering. In addition, the reinforcement structure 40 of the present embodiment can also be a deposition structure formed on the upper surface 11 of the immersion-type heat dissipation structure 10 by physical deposition or chemical deposition.

In addition, a number of the reinforcement structure 40 of the present embodiment can be multiple, and a projection area of each of the reinforcement structures 40 on the upper surface 11 of the immersion-type heat dissipation substrate 10 is at least two times larger than a projection area of each of the plurality of porous fins 21 on the upper surface 11 of the immersion-type heat dissipation substrate 10.

### Third Embodiment

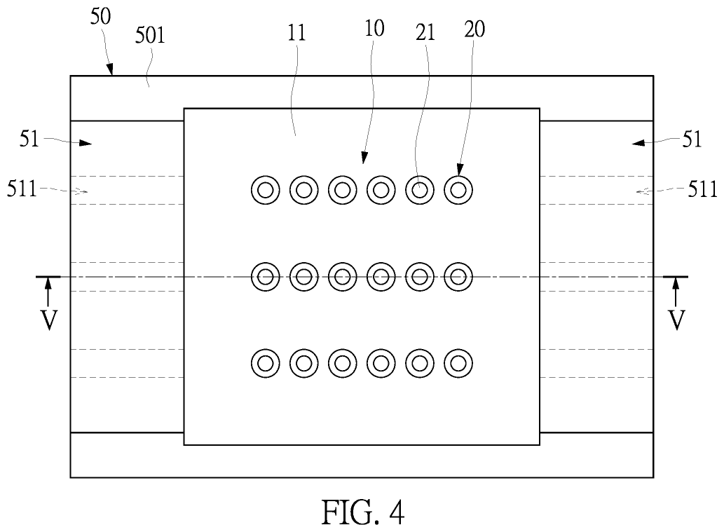

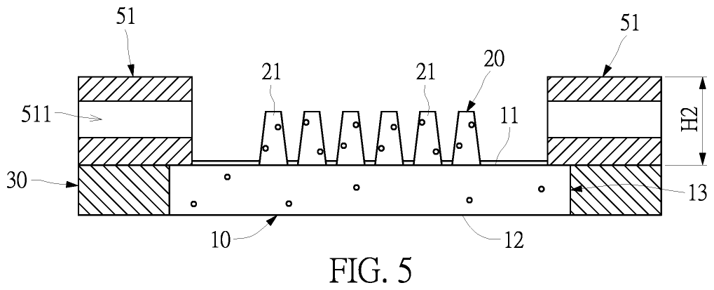

Reference is made to FIG. 4 and FIG. 5, in which a third embodiment of the present disclosure is shown. The third embodiment is substantially the same as the first embodiment, and differences therebetween are described as follows.

The two-phase immersion-type heat dissipation structure of the present embodiment essentially includes an immersion-type heat dissipation substrate 10, a fin assembly 20, a metal reinforcement frame 30, and a structural reinforcement member 50.

In the present embodiment, the metal reinforcement frame 30 is surroundingly in contact with a peripheral wall 13 of the immersion-type heat dissipation substrate 10. Furthermore, the structural reinforcement member 50 that has a frame shape is disposed on the metal reinforcement frame 30 and abuts a part of an upper surface 11 of the immersion-type heat dissipation substrate 10. The structural reinforcement member 50 can be made of copper, aluminum, titanium, iron, or alloys thereof. In addition, the structural reinforcement member 50 that has the frame shape has two reinforcement side walls 51 that protrude from a surface 501 of the structural reinforcement member 50. The two reinforcement side walls 51 are arranged opposite to each other and respectively abut a right side and a left side of the upper surface 11 of the immersion-type heat dissipation substrate 10. A height of each of the two reinforcement side walls 51 is configured to be between 5 mm and 15 mm, and each of the two reinforcement side walls 51 has a plurality of through holes 511 that horizontally pass through the reinforcement side wall 51, and are used for a replenishment of a two-phase coolant.

Furthermore, the upper surface 11 of the immersion-type heat dissipation substrate 10 of the present embodiment can also have a reinforcement structure 40 as shown in FIG. 3 formed thereon.

### Beneficial Effects of the Embodiments

In conclusion, in the two-phase immersion-type heat dissipation structure provided by the present disclosure, by virtue of the immersion-type heat dissipation substrate having the upper surface and the lower surface, the lower surface being used for contacting the heat generating element, and the upper surface having the fin assembly arranged thereon vertically, the metal reinforcement frame being surroundingly in contact with the peripheral wall of the immersion-type heat dissipation substrate, the metal reinforcement frame having the two reinforcement side walls that correspondingly protrude from a surface of the metal reinforcement frame, the two reinforcement side walls being arranged opposite to each other, the height of each of the two reinforcement side walls being between 5 mm and 15 mm, and each of the two reinforcement side walls having the plurality of through holes that horizontally pass through the reinforcement side wall and being used for the replenishment of the two-phase coolant, or the metal reinforcement frame being surroundingly in contact with the peripheral wall of the immersion-type heat dissipation substrate, the structural reinforcement member that has the frame shape being disposed on the metal reinforcement frame, the structural reinforcement member having the two reinforcement side walls that correspondingly protrude from the surface of the structural reinforcement member, the two reinforcement side walls being arranged opposite to each other and respectively abut the right side and the left side of the upper surface of the immersion-type heat dissipation substrate, the height of each of the two reinforcement side walls being between 5 mm and 15 mm, and each of the two reinforcement side walls having the plurality of through holes that horizontally pass through the reinforcement side wall and are used for the replenishment of the two-phase coolant, the overall structure and the two sides of the overall structure can be strengthened, so that a flexibility in controlling the porosity of the two-phase immersion-type heat dissipation structure can be increased on the basis of sufficient structural strength, thereby increasing the immersion-type heat dissipation effect. In addition, the two-phase coolant can be laterally replenished to the region where the vapor bubbles are generated, so as to further increase the immersion-type heat dissipation effect.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A two-phase immersion-type heat dissipation structure, comprising:
an immersion-type heat dissipation substrate;
a fin assembly; and
a metal reinforcement frame;
wherein the immersion-type heat dissipation substrate has an upper surface and a lower surface that are opposite to each other, the lower surface is used for contacting a heat generating element, and the upper surface has the fin assembly arranged vertically thereon;
wherein the metal reinforcement frame is surroundingly in contact with a peripheral wall of the immersion-type heat dissipation substrate, and the metal reinforcement frame has two reinforcement side walls that correspondingly protrude from a surface of the metal reinforcement frame;
wherein the two reinforcement side walls are arranged opposite to each other, and a height of each of the two reinforcement side walls is between 5 mm and 15 mm;
wherein each of the two reinforcement side walls has a plurality of through holes that horizontally pass through the reinforcement side wall and that are used for a replenishment of a two-phase coolant.

2. The two-phase immersion-type heat dissipation structure according to claim 1, wherein the immersion-type heat dissipation substrate is made of aluminum, copper, or alloys thereof, and the metal reinforcement frame is made of copper, aluminum, titanium, iron, or alloys thereof.

3. The two-phase immersion-type heat dissipation structure according to claim 2, wherein the immersion-type heat dissipation substrate is a porous metal heat dissipation substrate that has a porosity greater than 5% and that is immersed in the two-phase coolant.

4. The two-phase immersion-type heat dissipation structure according to claim 3, wherein the fin assembly includes a plurality of porous fins, and a porosity of the fin assembly is greater than the porosity of the immersion-type heat dissipation substrate.

5. The two-phase immersion-type heat dissipation structure according to claim 1, wherein the upper surface of the immersion-type heat dissipation substrate has at least one reinforcement structure formed thereon, the fin assembly includes a plurality of porous fins, and a projection area of the at least one reinforcement structure on the upper surface of the immersion-type heat dissipation substrate is two times or more larger than a projection area of any one of the plurality of porous fins on the upper surface of the immersion-type heat dissipation substrate.

6. A two-phase immersion-type heat dissipation structure, comprising:
an immersion-type heat dissipation substrate;
a fin assembly;
a metal reinforcement frame; and
a structural reinforcement member;
wherein the immersion-type heat dissipation substrate has an upper surface and a lower surface that are opposite to each other, the lower surface is used for contacting a heat generating element, and the upper surface has the fin assembly arranged vertically thereon;
wherein the metal reinforcement frame is surroundingly in contact with a peripheral wall of the immersion-type heat dissipation substrate, the structural reinforcement member that has a frame shape is disposed on the metal reinforcement frame, and the structural reinforcement member has two reinforcement side walls that correspondingly protrude from a surface of the structural reinforcement member;
wherein the two reinforcement side walls are arranged opposite to each other and respectively abut a right side and a left side of the upper surface of the immersion-type heat dissipation substrate, and a height of each of the two reinforcement side walls is between 5 mm and 15 mm;
wherein each of the two reinforcement side walls has a plurality of through holes that horizontally pass through the reinforcement side wall and that are used for a replenishment of a two-phase coolant.

7. The two-phase immersion-type heat dissipation structure according to claim 6, wherein the immersion-type heat dissipation substrate is made of aluminum, copper, or alloys thereof, the metal reinforcement frame is made of copper, aluminum, titanium, iron, or alloys thereof, and the structural reinforcement member is made of copper, aluminum, titanium, iron, or alloys thereof.

8. The two-phase immersion-type heat dissipation structure according to claim 7, wherein the immersion-type heat dissipation substrate is a porous metal heat dissipation substrate that has a porosity greater than 5% and that is immersed in the two-phase coolant.

9. The two-phase immersion-type heat dissipation structure according to claim 8, wherein the fin assembly includes a plurality of porous fins, and a porosity of the fin assembly is greater than the porosity of the immersion-type heat dissipation substrate.

10. The two-phase immersion-type heat dissipation structure according to claim 9, wherein the upper surface of the immersion-type heat dissipation substrate has at least one reinforcement structure formed thereon, the fin assembly includes a plurality of porous fins, and a projection area of the at least one reinforcement structure on the upper surface of the immersion-type heat dissipation substrate is two times or more larger than a projection area of any one of the plurality of porous fins on the upper surface of the immersion-type heat dissipation substrate.
